(19) United States
(12) Patent Application Publication
(10) Pub. No.: US 2024/0154392 A1
(43) Pub. Date: May 9, 2024

(54) ELECTRICAL CONNECTION BOX

(71) Applicant: Sumitomo Wiring Systems, Ltd., Yokkaichi-shi, Mie (JP)

(72) Inventor: Asuka MORI, Yokkaichi-shi, Mie (JP)

(21) Appl. No.: 18/264,002

(22) PCT Filed: Jan. 18, 2022
(86) PCT No.: PCT/JP2022/001598

§ 371 Date: Aug. 2, 2023

(30) Foreign Application Priority Data
Feb. 4, 2021 (JP) 2021-016302

(51) Int. Cl. H02B 1/20; B60R 16/023; H02G 3/08; H02G 5/08

(52) U.S. Cl. CPC H02B 1/20; H02G 3/081; H02G 5/08; B60R 16/0238

(57) ABSTRACT

An electrical connection box includes: a bus bar including a bus bar body portion and a bus bar terminal portion for connection to an external device; a box body in which the bus bar is provided; and a cover for covering the box body. The box body includes a first region the bus bar body portion is provided and covered by the cover, and a second region in which the bus bar terminal portion is provided and exposed without being covered by the cover.

### CROSS-REFERENCE TO RELATED APPLICATIONS

This application is the U.S. national stage of PCT/JP2022/001598 filed on Jan. 18, 2022, which claims priority of Japanese Patent Application No. JP 2021-016302 filed on Feb. 4, 2021, the contents of which are incorporated herein.

### TECHNICAL FIELD

The present disclosure relates to an electrical connection box.

### BACKGROUND

An electrical connection box (also called a “junction box”) is used in industrial products such as automobiles. An electrical connection box is used to connect external devices such as power supply devices, in-vehicle devices, or other electrical connection boxes to each other and supply power to those devices. For example, in order to supply power from a battery to each of a plurality of in-vehicle devices, a wire is connected from the battery to an electrical connection box, and wires are respectively connected from the electrical connection box to the in-vehicle devices. The electrical connection box includes a box body in which a bus bar is provided and a cover (e.g., see JP 2008-154412A).

An operation for connecting an electrical connection box to external devices is performed in assembly plants for products such as automobiles. In such assembly plants, an electrical connection box is obtained by providing a bus bar in a body box and attaching a cover to the body box in advance, and then the electrical connection box is fixed to a vehicle body frame of an automobile, for example. When connecting the bus bar of an external device to a terminal portion of the bus bar included in the electrical connection box, it is necessary to remove the cover of the electrical connection box to perform the operation for connecting the bus bar, and then attach the cover.

For this reason, in a production line for products such as automobiles, particularly when performing operations for connecting bus bars of external devices to terminal portions of a large number of electrical connection boxes, the time and effort taken to remove and attach the covers leads to a deterioration in work efficiency.

In view of this, an object of the present disclosure is to provide an electrical connection box that facilitates the operation for connecting an external device to a bus bar.

### SUMMARY

An electrical connection box according to an aspect of the present disclosure is an electrical connection box including: a bus bar including a bus bar body portion and a bus bar terminal portion for connection to an external device; a box body in which the bus bar is provided; and a cover configured to cover the box body, and the box body includes a first region in which the bus bar body portion is provided and covered by the cover, and a second region in which the bus bar terminal portion is provided and exposed without being covered by the cover.

### Advantageous Effects

According to the present disclosure, an operation for connecting an external device to a bus bar of an electrical connection box can be facilitated.

### BRIEF DESCRIPTION OF DRAWINGS

FIG. 1 is a perspective view of an electrical connection box according to the present embodiment.

FIG. 2 is an exploded perspective view of the electrical connection box shown in FIG. 1.

FIG. 3 is a perspective view showing a state where a cover is removed from a box body.

FIG. 4 is an illustrative view showing a state where the cover and a sensor are removed from the electrical connection box shown in FIG. 1.

FIG. 5 is a plan view of a portion of the electrical connection box.

FIG. 6 is a perspective view of a sensor as seen from below.

### DETAILED DESCRIPTION OF PREFERRED EMBODIMENTS

Hereinafter, an overview of embodiments of the present disclosure will be listed and described.

An electrical connection box according to the present embodiment includes: a bus bar including a bus bar body portion and a bus bar terminal portion for connection to an external device; a box body in which the bus bar is provided; and a cover configured to cover the box body, and the box body includes a first region in which the bus bar body portion is provided and covered by the cover, and a second region in which the bus bar terminal portion is provided and exposed without being covered by the cover.

According to the electrical connection box according to the present embodiment, while the bus bar body portion in the first region included in the box body is covered by the cover, the bus bar terminal portion in the second region included in the box body is exposed without covered by the cover. For this reason, the operation for connecting the external device to the bus bar terminal portion can be performed without removing the cover. In other words, the operation for connecting the external device to the bus bar of the electrical connection box can be facilitated. As a result, in particular, even when operations for connecting external devices to respective bus bar terminal portions of a large number of electrical connection boxes are performed, the efficiency in the operations can be improved. Preferably, the second region includes a sensor attachment portion to which a sensor for measuring a current flowing through the bus bar is attached, and the sensor is exposed together with the bus bar terminal portion without being covered by the cover.

In this case, an operation for removing and attaching the sensor may be performed without removing the cover. If a connector portion of the sensor to which a cable is to be connected is exposed, an operation for connecting a cable to the sensor can be performed without removing the cover.

Preferably, the bus bar includes a first member serving as the bus bar body portion attached to the first region, and a second member that includes the bus bar terminal portion and is removably connected to the first member, and the sensor is made in one piece with the second member, and detects a current flowing through the second member.

In this case, if the second member is removed from the first member, the sensor can be removed from the box body together with the second member.

Preferably, the second member is a conductor elongated in a first direction, one end side of the conductor being provided with the bus bar terminal portion, a current flowing through a center portion of the conductor being detected by the sensor, and another end side of the conductor being a connection portion connected to the first member, the cover includes a pair of cover side portions configured to cover the first member and the connection portion from two sides, and a cover body portion connecting the pair of cover side portions, and the cover body portion includes an opening allowing passage of the connection portion.

In this case, in the bus bar, the second member connected to the first member can be removed through the opening of the cover body portion. For this reason, even when the sensor is made in one piece with the second member, by removing the second member from the first member, removal of the sensor from the second region of the box body can be facilitated.

Preferably, the sensor attachment portion includes a recessed portion or a protruding portion to which a protruding portion or a recessed portion included in the sensor is fitted to position the sensor at a predetermined position.

In this case, positioning and attachment of the sensor to the second region can be facilitated.

More preferably, the protruding portion is fitted to the recessed portion in close contact. In this case, due to the protruding portion and the recessed portion engaging with each other, the sensor is fixed to a predetermined position of the second region.

Preferably, the second member is fixed to the first member by a bolt that fastens the second member to the first member in a direction in which the second member is overlaid on the first member, the protruding portion protrudes in a direction parallel with the direction in which the second member is overlaid on the first member, and the recessed portion is recessed in a direction parallel with the direction in which the second member is overlaid on the first member.

In this case, in the state where the positions of the protruding portion and the recessed portion are aligned, when the bolt is fastened to attach the second member, which is to be made in one piece with the sensor, to the first member, the protruding portion and the recessed portion are engaged with each other. As a result, the operation for attaching the sensor to the second region of the box body can be facilitated.

Hereinafter, details of the present disclosure will be described with reference to the drawings. Note that at least portions of the following embodiments can be combined as desired.

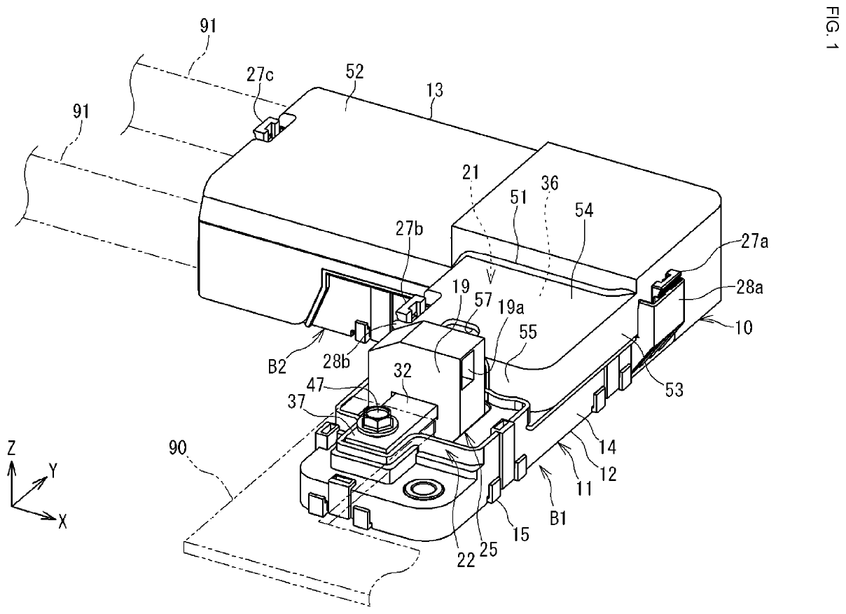

An electrical connection box 10 (see FIG. 1) of the present embodiment is for mounting in an automobile, for example, and used at an intermediate point along a path for supplying power from an in-vehicle battery to a plurality of in-vehicle devices (not shown). The electrical connection box 10 of the present embodiment may also be referred to as a relay electrical connection box. In an automobile assembly plant, an operation is performed for connecting bus bars and wire harnesses of external devices to the electrical connection box 10 fixed to a vehicle body frame of an automobile, for an example.

### Overall Configuration of Electrical Connection Box 10

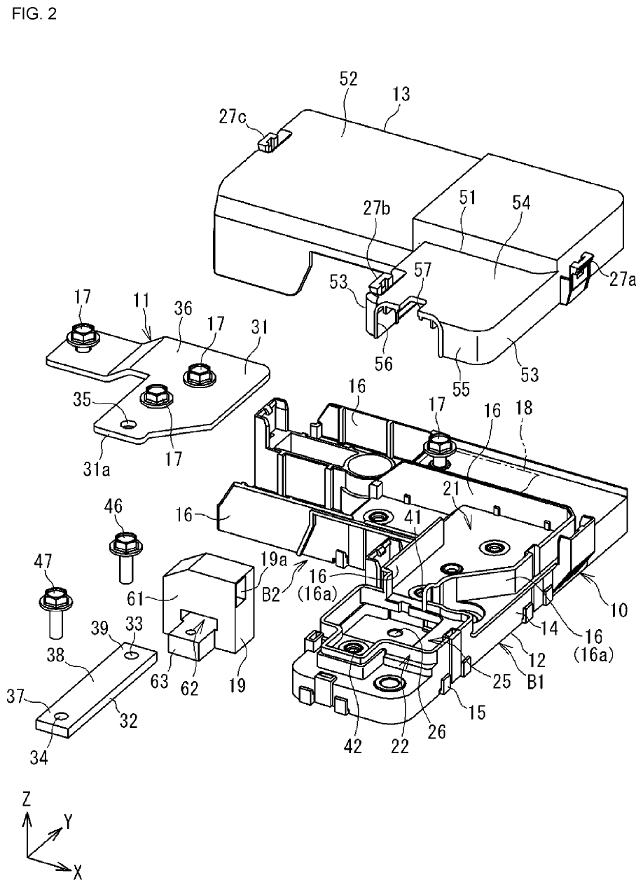

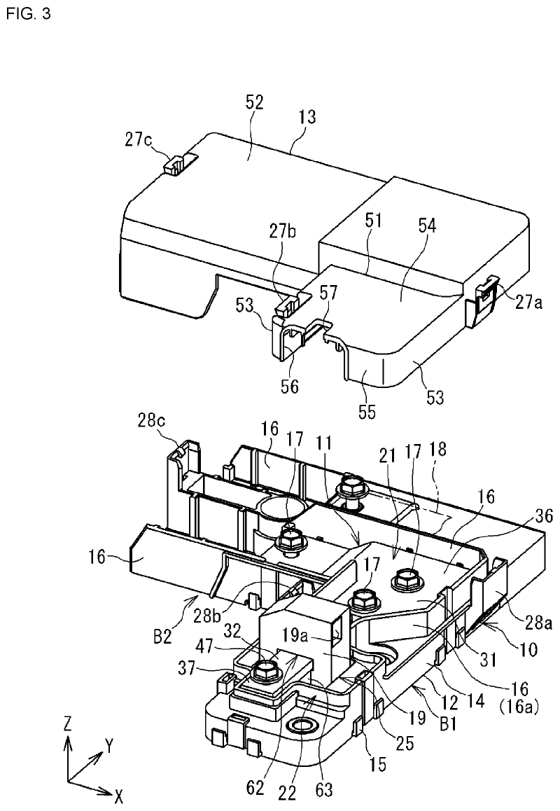

FIG. 1 is a perspective view of the electrical connection box 10 according to the present embodiment. In FIG. 1, a bus bar 90 for connection to a first external device and a wire harness 91 for connection to a second external device are shown by virtual lines (two-dot chain lines). FIG. 2 is an exploded perspective view of the electrical connection box 10 shown in FIG. 1. The electrical connection box 10 is provided with a bus bar 11, a box body 12 in which a bus bar 11 is provided, and a cover 13 for covering the box body 12. FIG. 3 is a perspective view showing a state where the cover 13 is removed from the box body 12.

The up-down direction, the front-rear direction, and the left-right direction are defined based on the electrical connection box 10 according to the present disclosure. Although the electrical connection box 10 has protrusions and recessions, overall, the electrical connection box has a flattened box-like shape. The flattened direction, that is, the direction along which the thickness of the electrical connection box 10 is smaller, is defined as the up-down direction. The electrical connection box shown in FIGS. 1 and 2 has a first block B1 whose longitudinal direction defines a first direction, and a second block B2 whose longitudinal direction defines a second direction that intersects (is orthogonal to) the first direction, and the electrical connection box 10 is substantially L-shaped as seen from above. In the present disclosure, the first direction is defined as the front-rear direction, and the second direction is defined as the left-right direction.

In the first block B1, the side on which the bus bar 90 for the first external device is connected will be referred to as the “front side”, and the side opposite to the first side and on which the second block B2 is connected will be referred to as the “rear side”. In the second block B2, the side on which the wire harness 91 for the second external device is connected will be referred to as the “left side”, and the side opposite to the left side will be referred to as the “right side”. XYZ rectangular coordinates are shown in the drawings. The Z direction is the direction that extends from below to above (the up-down direction), the Y direction is the front-rear direction (the direction that extends from front to rear), and the X direction is the left-right direction (the direction that extends from left to right).

The box body 12 includes a first case (upper case) 14 and a second case (lower case) 15. FIGS. 1, 2, and 3 show a state where the first case 14 is coupled to the second case 15. In FIG. 3, a main bus bar 11 is provided between the first case 14 and a cover 13. A sub bus bar (not shown) is provided between the first case 14 and the second case 15. The second case 15 covers the first case 14 from below. The cover 13 covers the first case 14 from above.

The first case 14, the second case 15, and the cover 13 are made of a synthetic resin, and molded through injection molding. Wall portions 16 that extend upward are provided at portions of the first case 14, and on the whole, the first case 14 is open upward. The bus bar 11 (first bus bar 11) is provided between a pair of wall portions 16 that oppose each other. In the present embodiment, in addition to the first bus bar 11, a second bus bar 18 shown by two-dot chain lines is also provided. The first bus bar 11 is substantially L-shaped as seen from above, and conforms to the shape of the box body 12. Note that the shapes of the electrical connection box (the box body 12) and the bus bar 11 can be freely changed and may be shapes other than an L shape.

A sensor 19 is attached to the electrical connection box 10. The sensor 19 is attached to the box body 12 together with the bus bar 11. The sensor 19 detects a current flowing through a portion of the bus bar 11 (a portion of the later-described second member 32) in a contactless manner. A detection signal from the sensor 19 is output to a control unit (not shown) via a cable connected to the connector portion 19a of the sensor 19. A current flowing through a conductive path in which the electrical connection box 10 is included is monitored by the sensor 19. The structure by which the sensor 19 is attached to the box body 12 will be described later.

The first bus bar 11 and the second bus bar 18 are attached to the box body 12 by bolts. As described later, the first bus bar 11 is constituted by a first member 31 and a second member 32. The second member 32 is removable for maintenance such as replacement of the sensor 19. Even when the second member 32 is removed, the first member 31 is not removed. Bolts that fix the first member 31 and are not removable at the time of maintenance will be referred to as “fixed bolts 17”. In contrast to this, bolts 46 and 47 other than the fixed bolts 17 are used for attachment and removal of the second member 32. The one bolt 46 will be referred to as a “first attachment bolt 46”, and the other bolt 47 will be referred to as a “second attachment bolt 47”.

The first bus bar 11 (hereinafter simply referred to as the “bus bar 11”) includes a bus bar body portion 36 and a bus bar terminal portion 37 for connection to the bus bar 90 for the first external device (see FIG. 1). As shown in FIG. 3, the bus bar body portion 36 and the bus bar terminal portion 37 are provided on the box body 12 and do not protrude from the box body 12. As shown in FIG. 1, the bus bar body portion 36 is covered by the cover 13, while the bus bar terminal portion 37 is not covered by the cover 13 and is exposed to the outside together with the sensor 19.

In the state where the cover 13 is attached to the box body 12, a region of the box body 12 in which the bus bar body portion 36 is provided and covered by the cover 13 is a “first region 21”. In the state where the cover 13 is attached to the box body 12, a region of the box body 12 in which the bus bar terminal portion 37 is provided and exposed without being covered by the cover 13 is a “second region 22”.

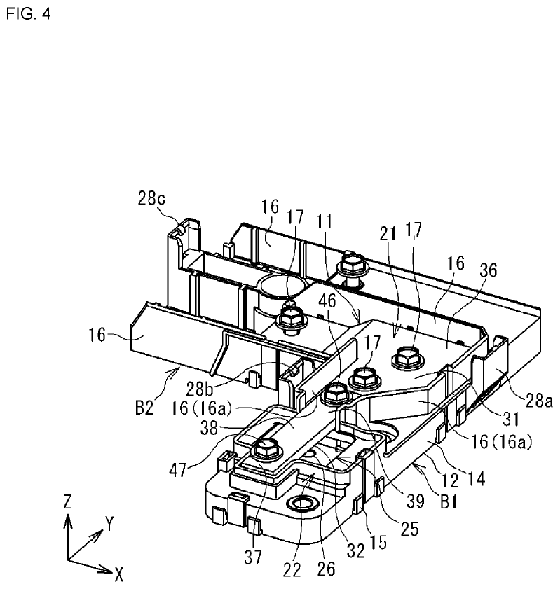

The bus bar 11 will be described in more detail. FIG. 4 is an illustrative diagram showing a state where the cover 13 and the sensor 19 have been removed from the electrical connection box 10 shown in FIG. 1. The bus bar 11 includes a first member 31 serving as the bus bar body portion 36 and a second member 32 that includes the bus bar terminal portion 37. The second member 32 is a separate member from the first member 31 and removably connected to the first member 31. The first member 31 is attached along the first region 21 using the fixed bolts 17. The second member 32 is a conductor elongated in the front-rear direction (the first direction). The bus bar terminal portion 37 is provided on one end side of the second member 32. A central portion 38 in the longitudinal direction of the second member 32 is a portion in which the current is to be detected by the sensor 19. Another end side of the second member 32 is a connection portion 39 for connection to the first member 31.

As shown in FIG. 2, a first bolt hole 41 for the first attachment bolt 46 is provided in a portion of the first region 21 of the box body 12. A through hole 35 that allows the first attachment bolt 46 to pass therethrough is formed in a portion of the first member 31. In a state where the first member 31 is fixed to the first region 21 using the fixed bolts 17, the through hole 35 of the first member 31 is at the same position as the first bolt hole 41, as seen from above.

A though hole 33 that allows the first attachment bolt 46 to pass therethrough is provided in the connection portion 39 of the second member 32. The connection portion 39 of the second member 32 is overlaid on the first member 31 provided in the first region 21. The first attachment bolt 46 is passed through the through hole 33 of the second member 32 and the through hole 35 of the first member 31, and fastened to the first bolt hole 41. That is, the first member 31 and the connection portion 39 of the second member 32 are fastened together to the box body 12 using the first attachment bolt 46.

A second bolt hole 42 is provided in the second region 22 of the box body 12. A through hole 34 that allows the second attachment bolt 47 to pass therethrough is formed in the bus bar terminal portion 37 of the second member 32. The second attachment bolt 47 is passed through the through hole 34 of the second member 32 and fastened to the second bolt hole 42. In this manner, the bus bar terminal portion 37 of the second member 32 is attached to the box body 12. Note that, when attaching the bus bar terminal portion 37 of the second member 32 to the box body 12 using the second attachment bolt 47, due to the second attachment bolt 47, the bus bar 90 (see FIG. 1) for the first external device is also fastened.

The wall portions 16 included in the box body 12 will now be described. A pair of wall portions 16a that covers the first member 31 from both sides are provided in the first region 21 of the first block portion B1 included in the box body 12. The interval in the left-right direction between the pair of wall portions 16a becomes narrower toward the front side. The width in the left-right direction of the front portion 31a of the first member 31 becomes narrower toward the front side, following the interval in the left-right direction between the pair of the wall portions 16a. The pair of wall portions 16a cover the connection portion 39 of the second member 32 that is overlaid on the first member 31, from both sides in the left-right direction (see FIG. 4). The second member 32 further extends frontward from a space between front end portions of the pair of wall portions 16a.

### Cover 13

In FIGS. 2 and 3, the cover 13 includes a first cover portion 51 for covering the first region 21 of the first block portion B1 of the box body 12, and a second cover portion 52 for covering the second block portion B2 of the box body 12. The first cover portion 51 includes a pair of cover side portions 53 for covering the pair of wall portions 16a from both sides in the left-right direction and a cover body portion 54 for connecting upper portions of the cover side portions 53. When the cover 13 is attached to the box body 12, the pair of cover side portions 53 cover a portion (front portion) of the first member 31 and a portion (connection portion 39) of the second member 32, provided between the pair of wall portions 16a, from both sides in the left-right direction.

Out of the two cover side portions 53, one cover side portion 53 (on the right side) includes a cover extension portion 55 that extends frontward. The cover extension portion 55 is connected to the cover body portion 54. An opening is formed between the cover extension portion 55 and the other cover side portion 53 (on the left side) out of the two cover side portions 53. The opening is a first opening portion 56. In the state where the second member 32 is attached to the box body 12, the second member 32 is passed through the first opening portion 56.

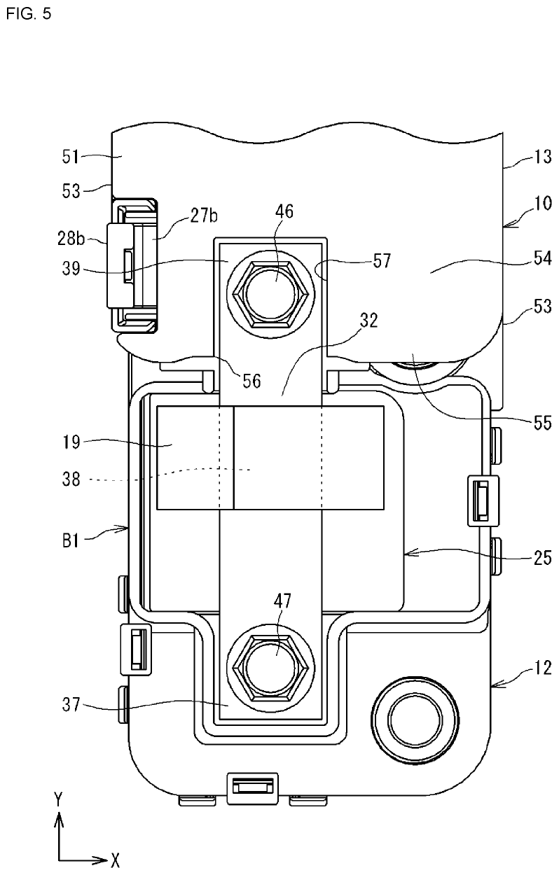

FIG. 5 is a plan view of a portion (first block portion B1) of the electrical connection box 10. In order to remove the second member 32 from the box body 12, an opening that allows the connection portion 39 of the second member 32 to pass therethrough is provided in the cover body portion 54. The opening is a second opening portion 57. As shown in FIGS. 2 and 3, the second opening portion 57 is formed on the front side of the cover body portion 54, and is continuous with the first opening 56.

The electrical connection box 10 includes a plurality of engaging portions and engaged portions for attaching the cover 13 to the box body 12. In FIG. 3, the box body 12 includes three engaged portions 28a, 28b, and 28c. The engaged portion 28a is provided on one side in the left-right direction of the first block B1 included in the box body 12, and the engaged portion 28b is provided on the other side in the left-right direction of the first block B1. The first engaged portion 28a is provided on the rear portion of the first block B1. The second block B2 extends leftward from the rear portion of the first block B1, and the engaged portion 28c is provided on the left side of the second block B2.

The cover 13 includes three engaging portions 27a, 27b, and 27c. In a state where the cover 13 is attached to a regular position of the box body 12, the three engaging portions 27a, 27b, and 27c engage with the three engaged portions 28a, 28b, and 28c. In this manner, the cover 13 is attached to the box body 12. Note that although the case where three of the engaged portions and three of the engaging portions are provided is described, the numbers may be changed.

### Sensor 19

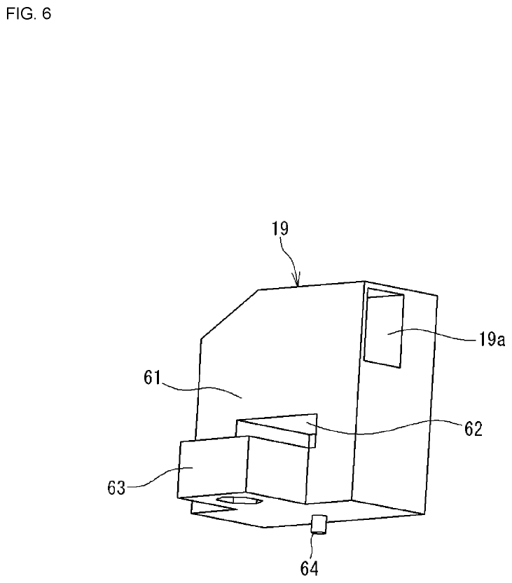

FIG. 6 is a perspective view showing a sensor 19 as seen from below. A housing body 61 of the sensor 19 includes a through hole 62. The second member 32 is passed through the through hole 62 (see FIG. 3). The sensor 19 is configured to detect a current flowing through a center portion of the second member 32 that is passed through the through hole 62.

In FIG. 6, the sensor 19 includes a base portion 63 as a portion of the housing body 61. An upper surface of the base portion 63 forms a portion of the through hole 62. In a state where the second member 32 is passed through the through hole 62 (see FIG. 3), the second member 32 is attached to the box body 12 by the first attachment bolt 46 and the second attachment bolt 47. In this manner, the base portion 63 of the sensor 19 is sandwiched between the second member 32 and the box body 12 in the up-down direction, and the sensor 19 is fixed to the box body 12 together with the second member 32. In other words, the sensor 19 is integrated with the second member 32 and fixed to the box body 12.

In FIGS. 3, and 4, a portion of the box body 12 to which the sensor 19 is fixed is referred to as a “sensor attachment portion 25”. The sensor attachment portion 25 is included in the second region 22 of the box body 12 that is not covered by the cover 13. That is, the second region 22 that is not covered by the cover 13 includes the sensor attachment portion 25. For this reason, in a state where the sensor 19 is attached to the sensor attachment portion 25 (see FIG. 1), the sensor 19 is exposed to the outside together with the bus bar terminal portion 37 included in the second member 32, without being covered by the cover 13.

As shown in FIG. 6, a lower surface of the housing body 61 of the sensor 19 includes a protruding portion 64 that protrudes downwards. As shown in FIG. 2, a recessed portion 26 to which the protruding portion 64 can be fitted is provided in the sensor attachment portion 25. The recessed portion 26 is constituted by a hole formed in the box body 12. In the state where the sensor 19 is attached to a predetermined position of the sensor attachment portion 25 together with the second member 32, the protruding portion 64 is fitted to the recessed portion 26. In other words, the sensor 19 is positioned and attached by the protruding portion 64 and the recessed portion 26.

In the present embodiment, the sensor 19 includes the protruding portion 64, and the box body 12 includes the recessed portion 26. However, in contrast to this, although not shown, the sensor 19 may include the recessed portion, and the box body 12 may include the protruding portion. In other words, in order to position the sensor 19 at a predetermined position, the recessed portion or the protruding portion is provided on the sensor attachment portion 25, and the protruding portion or the recessed portion is fitted to the recessed portion or the protruding portion included in the sensor 19. With this configuration, positioning and attachment of the sensor 19 with respect to the second region 22 of the box body 12 can be facilitated.

Further, in the present embodiment, the sizes of the protruding portion 64 and the recessed portion 26 are set such that the protruding portion 64 is fitted to recessed portion 26 in close contact. For example, the protruding portion 64 has a cylindrical shape, the recessed portion 26 is a hole having a shape that conforms to the cylinder, and the outer diameter of the protruding portion 64 is set slightly larger than the inner diameter of the recessed portion 26. Note that it is preferable that a taper surface is formed at the leading end of the protruding portion 64 or the opening end of the recessed portion 26 in order to facilitate insertion of the protruding portion 64 into the recessed portion 26. Due to the protruding portion 64 fitting to the recessed portion 26 in close contact, the sensor 19 is fixed to a predetermined position in the second region 22, and rattling of the sensor 19 can be suppressed.

A coupling structure of the first member 31 and the second member 32 that form the bus bar 11 will be described next with reference to FIG. 4. In a state where the second member 32 is overlaid on the first member 31, the first member 31 and the second member 32 are fixed to the box body 12 using the first attachment bolt 46. In other words, the direction in which the second member 32 is overlaid on the first member 31 is the up-down direction, and by fastening the first attachment bolt 46 in the up-down direction, the second member 32 is fixed to the first member 31.

The protruding portion 64 included in the sensor 19 protrudes in a direction parallel with the up-down direction (downward in the up-down direction). The recessed portion 26 of the sensor attachment portion 25 is recessed in a direction parallel with the up-down direction (downward in the up-down direction). Accordingly, in the state where the positions of the protruding portion 64 and the recessed portion 26 are aligned, in order to attach the second member 32 that is formed in one piece with the sensor 19 to the first member 31, when the first attachment bolt 46 and the second attachment bolt 47 are fastened, the protruding portion 64 can be gradually fitted to the recessed portion 26. Accordingly, an operation for attaching the sensor 19 to the second region 22 of the box body 12 can be facilitated.

### Electrical Connection Box 10 of the Present Embodiment

As described above, the electrical connection box 10 of the present embodiment includes the bus bar 11, the box body 12 in which the bus bar 11 is provided, and the cover 13 that covers the box body 12. The bus bar 11 includes the bus bar body portion 36 and the bus bar terminal portion 37 that is to be connected to the bus bar 90 for the first external device (see FIG. 1). The box body 12 includes the first region 21 and the second region 22. The first region 21 is a region in which the bus bar body portion 36 is provided and the bus bar body portion 36 is covered by the cover 13. The second region 22 is a region in which the bus bar terminal portion 37 is provided and exposed without being covered by the cover 13.

According to the electrical connection box 10 of the present embodiment configured as above, the bus bar terminal portion 37 in the second region 22 is exposed without being covered by the cover 13, while the bus bar body portion 36 in the first region 21 is covered by the cover 13. For this reason, the operation for connecting the bus bar 90 for the first external device to the bus bar terminal portion 37 can be performed without removing the cover 13. That is, the operation for connecting the bus bar 90 for the first external device to the bus bar 11 of the electrical connection box 10 is facilitated. As a result of this, even when performing operations for connecting the bus bars 90 for the first external devices to the respective bus bar terminal portions 37 of a larger number of electrical connection boxes 10 in a production line for automobiles, for example, the efficiency of the operations can be improved.

The second region 22 of the box body 12 includes the sensor attachment portion 25 for attaching the sensor 19 that measures a current flowing through the bus bar 11. The sensor 19 attached to the sensor attachment portion 25 is exposed together with the bus bar terminal portion 37 without being covered by the cover 13. Thus, it is possible to perform the operation for removing and attaching the sensor 19 without removing the cover 13. In the sensor 19, the connector portion 19a that is connected to the cable is exposed, and therefore the operation for connecting the cable to the sensor 19 can be performed without removing the cover 13.

The bus bar 11 includes the first member 31 serving as the bus bar body portion 36 attached to the first region 21, and the second member 32 that includes the bus bar terminal portion 37. The second member 32 is removably connected to the first member 31. The sensor 19 is made in one piece with the second member 32, and detects a current flowing through the second member 32. Accordingly, if the second member 32 is removed from the first member 31, the sensor 19 can be removed from the box body 12 together with the second member 32. Also, the sensor 19 can be attached to the box body 12 together with the second member 32. As a result, maintenance such as replacement of the sensor 19 can also be facilitated.

The second member 32 constituting the bus bar 11 is a conductor elongated in the front-rear direction, the front end side thereof having the bus bar terminal portion 37, and the rear end side thereof being the connection portion 39 connected to the first member 31. The cover 13 includes the pair of cover side portions 53 that cover the entirety of the first member 31 and the connection portion 39 of the second member 32 from both sides in the left-right direction, and the cover body portion 54 that connects the cover side portions 53 to each other. The cover body portion 54 is provided with the opening (second opening portion 57) and the connection portion 39 of the second member 32 can pass through the second opening portion 57.

For this reason, the second member 32 connected to the first member 31 can be removed from the opening (second opening portion 57) of the cover body portion 54. Accordingly, even if the sensor 19 is made in one piece with the second member 32, by removing the second member 32 from the first member 31, the sensor 19 can be easily removed from the box body 12.

In this manner, besides the configuration in which the cover body portion 54 is provided with the opening (second opening portion 57), a configuration is also possible in which the entirety of the vicinity of the second member 32 of the cover 13 is omitted. In other words, in the cover 13, the front portions of the cover side portions 53 and the front portion of the cover body portion 54 may be omitted. However, in this case, the connection portion between the first member 31 and the second member 32 are exposed in the left-right direction as well, and the operator may touch the part with their finger. In view of this, as in the present embodiment, due to the opening (second opening portion 57) provided in the cover body portion 54, it becomes unlikely for the operator to touch the connection portion between the first member 31 and the second member 32.

The embodiment described above is to be construed as being exemplary and non-limiting in all respects. The scope of the present disclosure is not defined by the description given above, but by the claims, and is intended to include all changes within the configuration described in the claims and the equivalents thereof.

1. An electrical connection box comprising:
a bus bar including a bus bar body portion and a bus bar terminal portion for connection to an external device;
a box body in which the bus bar is provided; and
a cover configured to cover the box body,
wherein the box body includes a first region in which the bus bar body portion is provided and covered by the cover, and a second region in which the bus bar terminal portion is provided and exposed without being covered by the cover.

2. The electrical connection box according to claim 1,
wherein the second region includes a sensor attachment portion to which a sensor for measuring a current flowing through the bus bar is attached, and
the sensor is exposed together with the bus bar terminal portion without being covered by the cover.

3. The electrical connection box according to claim 2,
wherein the bus bar includes a first member serving as the bus bar body portion attached to the first region, and a second member that includes the bus bar terminal portion and is removably connected to the first member, and
the sensor is made in one piece with the second member, and detects a current flowing through the second member.

4. The electrical connection box according to claim 3,
wherein the second member is a conductor elongated in a first direction, one end side of the conductor being provided with the bus bar terminal portion, a current flowing through a center portion of the conductor being detected by the sensor, and another end side of the conductor being a connection portion connected to the first member,
the cover includes a pair of cover side portions configured to cover the first member and the connection portion from two sides, and a cover body portion connecting the pair of cover side portions, and
the cover body portion includes an opening allowing passage of the connection portion.

5. The electrical connection box according to claim 2,
wherein the sensor attachment portion includes a recessed portion or a protruding portion to which a protruding portion or a recessed portion included in the sensor is fitted to position the sensor at a predetermined position.

6. The electrical connection box according to claim 5,
wherein the protruding portion is fitted to the recessed portion in close contact.

7. The electrical connection box according to claim 5,
wherein the second member is fixed to the first member by a bolt that fastens the second member to the first member in a direction in which the second member is overlaid on the first member,
the protruding portion protrudes in a direction parallel with the direction in which the second member is overlaid on the first member, and
the recessed portion is recessed in a direction parallel with the direction in which the second member is overlaid on the first member.

8. The electrical connection box according to claim 3,
wherein the sensor attachment portion includes a recessed portion or a protruding portion to which a protruding portion or a recessed portion included in the sensor is fitted to position the sensor at a predetermined position.

9. The electrical connection box according to claim 4,
wherein the sensor attachment portion includes a recessed portion or a protruding portion to which a protruding portion or a recessed portion included in the sensor is fitted to position the sensor at a predetermined position.

10. The electrical connection box according to claim 6,
wherein the second member is fixed to the first member by a bolt that fastens the second member to the first member in a direction in which the second member is overlaid on the first member,
the protruding portion protrudes in a direction parallel with the direction in which the second member is overlaid on the first member, and
the recessed portion is recessed in a direction parallel with the direction in which the second member is overlaid on the first member.
